(19) United States
(12) Patent Application Publication
(10) Pub. No.: US 2011/0168257 A1
(43) Pub. Date: Jul. 14, 2011

(54) Solar Cell Structure

(76) Inventor: Vladimir Kochergin, Christiansburg, VA (US)

(21) Appl. No.: 12/684,970

(22) Filed: Jan. 11, 2010

(51) Int. Cl. H01L 31/0256; H01L 31/04; H01L 31/0368; H01L 31/036; H01L 31/0272; H01L 31/0296; H01L 31/0304; H01L 31/18

(52) U.S. Cl. 136/258; 136/252; 136/262; 136/260; 136/264; 136/263; 438/98; 977/773; 977/734; 977/742; 257/E31.124

(57) ABSTRACT

Utilization of the near percolation plasmonic nanostructures near the photoconversion layer in photovoltaic device provide significant enhancement in the efficiency. Photovoltaic devices utilizing efficiency enhancement due to utilization of near percolation plasmonic nanostructures and methods of photovoltaic device fabrication provide an improved solar cells that can be used for power generation and other applications.

### CROSS-REFERENCES TO RELATED APPLICATIONS

Not applicable.

### STATEMENT REGARDING FEDERALLY SPONSORED RESEARCH OR DEVELOPMENT

Not applicable.

### FIELD OF THE INVENTION

The present invention is related to a photovoltaic structure. In more detail, the present invention is related to the plasmon-enhanced photovoltaic structure utilizing plasmon-enhanced absorption and improved conversion efficiency. The apparatus of the present invention can be applied to solar energy generation used for utilities and other applications.

### BACKGROUND OF THE INVENTION

A large number of different solar cell and photovoltaic structures are known to those skilled in the art. This includes crystalline silicon, amorphous silicon, multijunction, and organic photovoltaic devices to name a few. The common problem of these devices (except the multijunction solar cells, which are too expensive for most applications) is the need to utilize optically “thick” photovoltaic absorbers (or active layers, which are typically semiconductors) to enable efficient light absorption and photocarrier current collection. For example, for crystalline silicon, the required thickness is greater than 50 microns, and it is several microns for direct bandgap compound semiconductors. High efficiency cells must have minority carrier diffusion lengths exceeding the active layer thickness by several times. This represents serious problem and tradeoff for a number of commonly used solar cell materials, most prominent for organic solar cells.

Most organic semiconductors are characterized by high energy and narrow-band absorption; as a result, only a fraction of the solar spectrum may be utilized for photovoltaic conversion. Despite the great potential of organic photovoltaics, efficiencies achieved to date are rather low, although constantly improving: very recently Solarmer Energy achieved a certified by NREL record for efficiency of 7.9%. However, roll-to-roll conversion efficiencies for organic solar cells are typically significantly lower than the record numbers (as with any other technology) and are still insufficient to meet the needs of most applications. To improve the conversion efficiency several problems have to be solved. First, the limited absorption range of current materials leads to inefficient photon harvesting. A red-shift of the absorption of the active layer materials (while keeping the absorption at blue part of the spectrum at high levels) is needed to more efficiently harvest photons provided by the sun. The low charge carrier mobility in organic materials limits the possible active layer thickness. Novel device structures are needed to overcome the low mobility.

Utilization of plasmon enhancement of photovoltaic conversion efficiency is an active area of research and development at present due to the promise of significant enhancement of the conversion efficiency of the solar cell with little-to-none required modification of the semiconductor materials used. In other words, the well-developed manufacturing technologies can be used for active layer fabrication. Two main basic mechanisms have been proposed to explain photocurrent enhancement by metal particles incorporated into or on solar cells: light scattering and near-field concentration of light. The contribution of each mechanism depends mostly on the particle size, how strongly the semiconductor absorbs and the electrical design of the solar cell.

The following prior art is incorporated here as a reference:

Stenzel, et al. [O. Stenzel, A. Stendal, K. Voigtsberger, C. von Borczykowski, Sol. Energy Mater. Sol. Cells 37 (1995)] demonstrated the enhancement of the photocurrent when utilizing metal nanoparticles in solar-cell structures for ITO-copper phthalocyanine-indium structures.

Stuart and Hall [H. R. Stuart and D. G. Hall, “Island size effects in nanoparticle-enhanced photodetectors” Appl. Phys. Lett. 73, 3815 (1998)] showed that an enhancement in the photocurrent of a factor of 18 could be achieved for a 165 nm thick silicon-on-insulator photo-detector at a wavelength of 800 nm using silver nanoparticles on the surface of the device.

M. Westphalen et al. [“Metal cluster enhanced organic solar cells”, Solar Energy Materials & Solar Cells 61 (2000) 97-105] demonstrated the enhancement of the photocurrent in organic photovoltaic devices utilizing Ag nanoparticles embedded in zinc phthalocyanine between the active layer and ITO electrode.

Rand et al. [B. P. Rand, P. Peumans, and S. R. Forrest, “Long-range absorption enhancement in organic tandem thinfilm solar cells containing silver nanoclusters,” J. Appl. Phys. 96, 7519 (2004)] have reported enhanced efficiencies for ultra-thin film organic solar cells due to the presence of 5 nm diameter silver nanoparticles.

Schaadt et al. [D. M. Schaadt, B. Feng, and E. T. Yu, “Enhanced semiconductor optical absorption via surface plasmon excitation in metal nanoparticles,” Appl. Phys. Lett. 86, 063106 (2005)] deposited gold nanoparticles on highly doped wafer-based solar cells, obtaining enhancements of up to 80% at narrow wavelength band around 500 nm.

Derkacs et al. [D. Derkacs, S. H. Lim, P. Matheu, W. Mar, and E. T. Yu, “Improved performance of amorphous silicon solar cells via scattering from surface plasmon polaritons in nearby metallic nanoparticles,” Appl. Phys. Lett. 89, 093103 (2006)] used Au nanoparticles on thin film amorphous silicon solar cells to achieve an 8% overall increase in conversion efficiency.

Enhanced efficiency in a different structure utilizing the “antennae” layer and plasmon-mediated energy transfer was demonstrated by T. D. Heidel et al., [“Surface plasmon polariton mediated energy transfer in organic photovoltaic devices,” APPLIED PHYSICS LETTERS 91, 093506 (2007)]. In such a realization the light absorption was decoupled from exciton diffusion using a light absorbing “antenna” layer external to the conventional charge generating layers. Radiation absorbed by the antenna was transferred into the charge generating layers via surface plasmon polaritons in an interfacial thin silver contact. The peak efficiency of energy transfer was measured to be at least 51±10%. Still, the spectrally and angularly-integrated conversion efficiency while not reported was probably way lower similarly to the case of Mapel et al.

Significant absorption enhancement with plasmon nanoparticles in silicon-based photovoltaic devices was demonstrated by depositing silver particles on 1.25 μm thick silicon-on-insulator solar cells and planar wafer based cells, and achieved overall photocurrent increases of 33% and 19% respectively [S. Pillai, K. R. Catchpole, T. Trupke, and M. A. Green, “Surface plasmon enhanced silicon solar cells,” JOURNAL OF APPLIED PHYSICS 101, 093105 (2007)].

Increased photocurrent has also been reported for CdSe/Si heterostructures [R. B. Konda, R. Mundle, H. Mustafa, O. Bamiduro, A. K. Pradhan, U. N. Roy, Y. Cui, and A. Burger, “Surface plasmon excitation via Au nanoparticles in n-CdSe/p-Si heterojunction diodes,” Appl. Phys. Lett. 91, 191111 (2007)].

Doubling of the quantum efficiency was demonstrated [J. K. Mapel et al., “Plasmonic excitation of organic double heterostructure solar cells,” APPLIED PHYSICS LETTERS 90, 121102 (2007)] in fullerene-copper phthalocyanine photovoltaic cells utilizing surface plasmon generation in Kretchmann (prism) geometry at resonance conditions (limited angular and spectral range of illumination). However, the effect on total (angular and spectrally-integrated) quantum efficiency was not reported and most probably was quite small.

Morfa et al. have reported an increase in efficiency by a factor of 1.7 for organic bulk heterojunction solar cells [A. J. Morfa, K. L. Rowlen, T. H. Reilly III, M. J. Romero, and J. v. d. Lagemaatb, “Plasmon-enhanced solar energy conversion in organic bulk heterojunction photovoltaics,” Appl. Phys. Lett. 92, 013504 (2008).].

Enhanced carrier generation has been observed in dye-sensitized TiO₂ films [C. Hagglund, M. Zäch, and B. Kasemo, “Enhanced charge carrier generation in dye sensitized solar cells by nanoparticle plasmons,” Appl. Phys. Lett. 92, 013113 (2008)].

U.S. Pat. No. 4,482,778 “Solar energy converter using surface plasma waves” issued to Anderson, Lynn M. issued on Nov. 13, 1984 is disclosing an apparatus for converting sunlight to electricity by extracting energy from photons therein comprising an electrically conducting member, and means for dispersing sunlight over a surface of said member to polarize the surface charge thereon thereby inducing oscillations in the valence electron density at said surface to produce surface plasmons and for phase-matching photons and surface plasmons of the same energy so that energy is transferred from said photons to said plasmons, and means for extracting energy from said surface plasmons and converting the same to electricity. Prisms, lenses, diffraction gratings, or textured surfaces are suggested as means for phase-matching between a photon and a slightly slower plasmon of the same energy. The main disadvantage of this invention is generally narrow band of conversion efficiency enhancement in such an apparatus due to spectrally narrow (resonant) phase matching conditions between photons and surface plasmon, leading to very small if any overall improvement of the photovoltaic device performance.

U.S. Pat. No. 4,554,727 “Method for making optically enhanced thin film photovoltaic device using lithography defined random surfaces” issued on Nov. 26, 1985 to H. W. Deckman et al. is teaching a method for producing an optically enhanced thin film photovoltaic semiconductor device having electrical contacts to carry current from said device comprising producing an active layer of semiconductor material wherein the surface of at least one side of said active layer is textured such that said surface includes randomly spaced, densely packed microstructures of predetermined dimensions of the order of the wavelength of visible light in said semiconductor material, said microstructure being microcolumnar posts having a predetermined profile such that said texture of said active layer results in optically enhancement by incoherent scattering with a randomization fraction, β, greater than 0.75; and further comprising forming a reflecting surface directly to either side of said semiconductor material and making an ohmic contact to said material such that the parasitic optical absorption in said electrical contacts and said reflecting surface are less than 1/n², where n is the semiconductor index of refraction, such that the enhancement factor, E, for optical absorption within the active layer of the semiconductor material and the quantum efficiency of collection of photogenerated carriers in increased by a factor greater than 1.5 n². Cu, Ag and Au materials were suggested as plasmonic materials, while materials like Al, Ni, Cr and Pt were specifically claimed to have too much absorption to produce a significant optical enhancement. The photovoltaic devices according to referenced invention demonstrated very significant and broadband light collection efficiency enhancement in the IR spectral range while no enhancement in the near UV or visible range was achieved thus providing far from desired spectral response for general purpose photovoltaic devices.

U.S. Pat. No. 5,685,919 “Method and device for improved photoelectric conversion” issued on Nov. 11, 1997 to Kazuhiro Saito, et al. is teaching a device for photoelectric conversion, comprising two thin metallic electrodes respectively located on the side where light is incident, and on the side opposite to the side of light incidence; further comprising a light absorbing layer sandwiched between the two thin metallic electrodes; and an optical transmission layer and an optical path changing layer formed in this order on the metallic electrode located on the side of light incidence, with the adjacent members being in intimate contact with each other; wherein the optical path changing layer has the function to refract incident light and cause it to be incident on the optical transmission layer at a desired angle, the refractive index of the optical transmission layer is smaller than the refractive index of the optical path changing layer, and the thickness of the optical transmission layer is about a half of the wavelength of the incident light. The disadvantage of this apparatus is spectrally and angularly narrow band of enhancement of photoelectric conversion efficiency.

U.S. Pat. No. 6,441,298 “Surface-plasmon enhanced photovoltaic device” issued on Aug. 27, 2002 to Tineke Thio is teaching a surface-plasmon enhanced photovoltaic device including: a first metallic electrode having an array of apertures, an illuminated surface and an un-illuminated surface, at least one of the surfaces having an enhancement characteristic resulting in a resonant interaction of incident light with surface plasmons; a second electrode spaced from the first metallic electrode; and a plurality of spheres corresponding to the array of apertures and disposed between the first metallic and second electrodes, each sphere having a first portion of either p or n-doped material and a second portion having the other of the p or n-doped material such that a p-n junction is formed at a junction between the first and second portions. The main disadvantage of the referenced photovoltaic device is generally narrow spectral range of surface Plasmon enhancement of the photoresponse, poorly overlapping with solar spectrum.

U.S. Pat. No. 6,685,986 “Metal nanoshells” issued on Feb. 3, 2004 to S. J. Oldenburg et al. is teaching the method of production of nonconducting core/conducting shell nanoparticles and suggesting that utilization of such nanoparticles in solar cells will provide enhanced photovoltaic conversion efficiency. While this invention provides some means to adjust the spectral position of the Plasmon resonance absorption peak, it still provides the means for narrow spectral range of enhanced photoconversion efficiency.

Utilization of plasmonic enhancement of photovoltaic devices is extensively covered in the US Patent Application #20070289623 “Plasmonic Photovoltaic” by H. Atwater, filed June 2007. This patent application teaches a surface plasmon polariton photovoltaic absorber, comprising: a substrate; at least one absorber layer disposed on said substrate, said absorber layer having a surface; a layer of conductive material comprising a surface plasmon polariton guiding layer disposed on said surface of said at least one absorber layer; and at least two electrodes, a first of which electrodes is in electrical communication with a first charge collection region of said photovoltaic absorber in which electrical charges of a first polarity are concentrated, and a second of which electrodes is in electrical communication with a second charge collection region of said photovoltaic absorber in which electrical charges of a second polarity are concentrated; said surface plasmon polariton photovoltaic absorber configured to generate an electrical potential between said first and said second electrodes when said surface plasmon polariton photovoltaic absorber is illuminated with electromagnetic radiation. It is further taught that the surface plasmon polariton photovoltaic absorber further comprise metallic nanoparticles selected one of silver, gold, copper and aluminum. Alternatively, it is taught that the surface plasmon polariton photovoltaic absorber may comprise conductive layer as a metallic structure in a form of a thin film comprising a metal selected from one of silver, gold, copper and aluminum. The disadvantage of such a device is still the too narrow spectral and/or angular band of enhanced photovoltaic conversion.

The disadvantage of all the disclosed so far plasmonic photovoltaic structures is the limited (spectrally and/or angularly) band of conversion efficiency enhancement, which in turn limits the overall plasmonic improvement of the solar energy generation. On the other hand, it is well known to those skilled in the art that the absorption/enhanced electromagnetic field band increases dramatically in plasmonic nanocomposites near the percolation threshold. Utilization of such a strategy in photovoltaic devices would provide the much needed wide band of significant conversion efficiency enhancement. Unfortunately, the widening of the plasmonic band in such nanostructures is typically accompanied with significant red-shifting of the band from visible to near IR wavelengths (for gold or silver composites) accompanied by the reduction of the absorption in the blue portion of the spectrum, reducing the potential utility of such an approach for solar cells.

### SUMMARY OF THE INVENTION

It is an object of the present invention to provide an improved photovoltaic device utilizing plasmon resonance-based enhancement of the photoelectric conversion efficiency which will resolve the majority of deficiencies of prior art approaches and will provide external quantum efficiency of organic photovoltaic devices compatible to that of thin film silicon photovoltaic devices or, if applied to nonorganic photovoltaic devices, will significantly improve the conversion efficiency beyond what is available with state of the art devices. It is another object of the present invention to provide a method of manufacturing of the photovoltaic device of the present invention.

The most important feature of the present invention is utilization of plasmonic nanostructures near the metal percolation threshold conditions provided in or around the active layer. For a nonlimiting example, such photovoltaic device if realized with organic active layer has the potential to provide the conversion efficiency at the level of standard silicon photovoltaic technology, while keeping all the benefits of organic PV technology, such as flexibility and possibility for low cost production. In such a realization the photovoltaic device of the present invention will effectively marry the most attractive features of presently developed organic PV devices (low cost, flexible structures) with those of inorganic solar cells (high conversion efficiency). The exemplary structure of the organic photovoltaic device utilizing plasmonic nanostructure near percolation limit will significantly enhance the absorption of the solar radiation in the active layer of the solar cell over the wide spectral range from blue range to mid IR range, thus providing the opportunity to use much thinner active layers, which in turn allows highly efficient transport of the free carriers to the collecting electrodes (reducing the electron-hole recombination, the main obstacle in improving the efficiency of the organic PV devices).

If realized with inorganic photoconversion layers, the photovoltaic device of the present invention will also provide the opportunity to significantly enhance the performance of cells by increasing the efficiency across the wide spectral band.

According to the first embodiment of the present invention the Plasmon-enhanced photovoltaic device is comprising a substrate; at least one photoconversion layer disposed on said substrate, said photoconversion layer having a surface, and two charge collection regions; a plasmonic nanostructure layer made of metal and disposed on said surface of said at least one photoconversion layer, said plasmonic nanostructure layer having plasmonic modes of electromagnetic field, such as electromagnetic field of said plasmonic modes is at least partially localized in said photoconversion layer; said plasmonic nanostructure layer having concentration of metal close to percolation threshold and at least two electrodes. First of which electrodes is in electrical contact with a first charge collection region of said photoconversion layer in which electrical charges of a first polarity are concentrated, and a second of which electrodes is in electrical contact with a second charge collection region of said photoconversion layer in which electrical charges of a second polarity are concentrated; said Plasmon-enhanced photovoltaic device configured to generate an electrical potential between said first and said second electrodes when said Plasmon-enhanced photovoltaic device is illuminated with electromagnetic radiation.

According to the first aspect of the present embodiment said plasmonic nanostructure layer is composed of metal nanoparticles disposed near the active layer, said metal made of material selected from the group consisted of Au, Ag, Cu and Al.

According to another aspect of the present embodiment said plasmonic nanostructure layer is comprising the nanolayered nanospheres with individual layers made of materials consisted of Au, Ag, Cu, Al, metal and semiconductor oxides.

According to still another aspect of the present embodiment said plasmonic nanostructure layer comprises the nanolayered nanoellipsoids with individual layers made of materials consisted of Au, Ag, Cu, Al, metal and semiconductor oxides.

According to still another aspect of the present embodiment said plasmonic nanostructure layer is composed from nanoparticles of at least two different materials selected from the group consisted of Au, Ag, Cu and Al.

According to still another aspect of the present embodiment said plasmonic nanostructure layer is composed from nanoparticles of at least two different structures in a form of multilayer spheres or ellipsoids selected from the group consisted of Au, Ag, Cu and Al, and metal oxides.

According to still another aspect of the present embodiment said plasmonic nanostructure plasmonic layer is composed of metal nanoparticles disposed near the active layer is comprising two or more materials of material selected from the group consisted of Au, Ag, Cu, Al, Si, Ni, Mo, Ta, Ti, Co, Fe.

According to the second embodiment of the present invention, a Plasmon-enhanced photovoltaic device is comprising a substrate; at least one photoconversion layer, said photoconversion layer two charge collection regions; a plasmonic nanostructure layer made of metal and disposed on said substrate, said plasmonic nanostructure layer having plasmonic modes of electromagnetic field, such as electromagnetic field of said plasmonic modes is at least partially localized in said photoconversion layer; said plasmonic nanostructure layer having concentration of metal close to percolation threshold; and at least two electrodes, a first of which electrodes is in electrical contact with a first charge collection region of said photoconversion layer in which electrical charges of a first polarity are concentrated, and a second of which electrodes is in electrical contact with a second charge collection region of said photoconversion layer in which electrical charges of a second polarity are concentrated; said Plasmon-enhanced photovoltaic device configured to generate an electrical potential between said first and said second electrodes when said Plasmon-enhanced photovoltaic device is illuminated with electromagnetic radiation. The structure of the plasmonic nanostructure layer is the same as described in relation to different aspects of the first embodiment of the present invention.

According to the third embodiment of the present invention, a plasmon-enhanced photovoltaic device can be fabricated by providing a substrate, applying, onto said substrate, first electrode, applying, onto said first electrode, a plasmonic nanostructure layer made of metal, said plasmonic nanostructure layer having concentration of metal close to percolation threshold, applying, onto said plasmonic nanostructure layer, a photoconversion layer, and applying, onto said photoconversion layer a second electrode.

According to the fourth embodiment of the present invention, A method of manufacturing a Plasmon-enhanced photovoltaic device: providing a substrate, applying, onto said substrate, first electrode, applying, onto said first electrode, a photoconversion layer, applying, onto said photoconversion layer, a plasmonic nanostructure layer made of metal, said plasmonic nanostructure layer having concentration of metal close to percolation threshold, applying and applying, onto said photoconversion layer a second electrode.

According to still another embodiment of the present invention two or more layers of nanocomposite plasmonic structures are used in a photovoltaic device with each of said layers having the structure described in previous embodiments of the present invention.

Said nanocomposite plasmonic layer of the present invention can be made by the process of chemical synthesis, deposition, sputtering, coating, electrodeposition, electroless deposition or any other method know by those skilled in the art.

Said photovoltaic structure can be organic photovoltaic structure, crystalline silicon photovoltaic structure, thin film amorphous silicon photovoltaic structure, CIS (Copper Indium Deselenide) photovoltaic structure or any other structure known to those skilled in the art.

Antireflection coating, structuring and concentration elements such as those used presently in the art can be used with the or in the photovoltaic structure of the present invention.

The photovoltaic structure of the present invention can be used in solar energy generation, photovoltaic conversion, photon detection and in other applications of photovoltaic structure presently known to those skilled in the art.

### BRIEF DESCRIPTION OF THE DRAWINGS

These and other features and advantages of presently preferred non-limiting illustrative exemplary embodiments will be better and more completely understood by referring to the following detailed description in connection with the drawings, of which:

FIG. 1 is a schematic drawing illustrating Plasmon-enhanced photovoltaic device according to the first embodiment of the present invention.

FIG. 2 Simulations illustrating the local average intensity enhancement for the plasmonic nanostructures far (prior art) and close (the subject of the present invention) to percolation threshold.

FIG. 3 is an exemplary illustrative drawing of a section of the Plasmon-enhanced photovoltaic device of the present invention employing nanolayered plasmonic nanospheres;

FIG. 4 is an exemplary illustrative drawing of a section of the Plasmon-enhanced photovoltaic device of the present invention employing nanolayered plasmonic nanoellipsoids;

FIG. 5 is an exemplary illustrative drawing of a section of the Plasmon-enhanced photovoltaic device of the present invention employing more than two kinds of plasmonic nanoparticles.

FIG. 6 is a schematic drawing illustrating Plasmon-enhanced photovoltaic device according to the second embodiment of the present invention.

FIG. 7 is a schematic drawing illustrating method of manufacturing of Plasmon-enhanced photovoltaic device according to the third embodiment of the present invention.

FIG. 8 is a schematic drawing illustrating method of manufacturing of Plasmon-enhanced photovoltaic device according to the fourth embodiment of the present invention.

### DESCRIPTION OF THE INVENTION

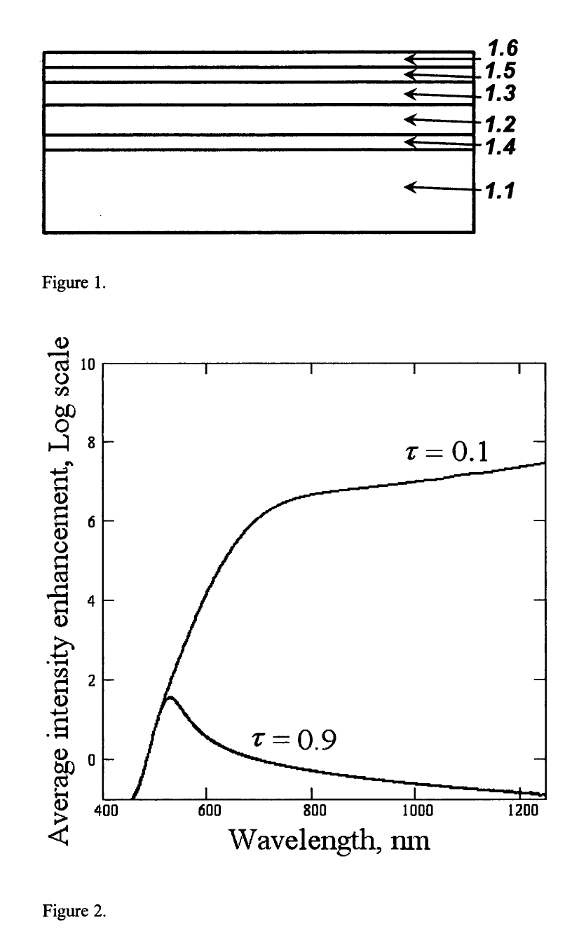

According to the first embodiment of the present invention the Plasmon-enhanced photovoltaic device shown in FIG. 1 is comprising a substrate 1.1; at least one photoconversion layer 1.2 disposed on said substrate, a plasmonic nanostructure layer 1.3 disposed on the surface of photoconversion layer, said plasmonic nanostructure layer having concentration of metal close to percolation threshold. and at least two electrodes 1.4 and 1.5, a first of which electrodes is in electrical contact with a first charge collection region of photoconversion layer in which electrical charges of a first polarity are concentrated, and a second of which electrodes is in electrical contact with a second charge collection region of said photoconversion layer in which electrical charges of a second polarity are concentrated. Additional protection and/or antireflection layer 1.6 can be employed in photovoltaic device as well to further improve the performance.

The photoconversion layer can be made of polycrystalline, single-crystal or amorphous form of semiconductor material is selected from the group consisting of silicon, GaAs, CdTe, CuInGaSe (CIGS), CdSe, PbS, and PbSe. Alternatively, the photoconversion layer can be made of a photosensitized nanomatrix material, which can contain semiconductor nanoparticles. Alternatively , the photoconversion layer can be made of a photosensitized nanomatrix material, which can contain one or more types of interconnected metal oxide nanoparticles, said metal oxide has the formula MₓO_{y} wherein M is selected from the group consisting of Ti, Zr, W, Nb, La, Ta, Tb, Sn, and Zn; and x and y are integers greater than 0. The metal oxide nanoparticles can be interconnected by a polymeric linking agent. Said photosensitized nanomatrix material can comprise a photosensitizing agent selected from the group consisting of dyes, xanthenes, cyanines, merocyanines, phthalocyanines, and pyrroles. Moreover, the photoconversion layer of the present invention can be made of heterojunction composite material. The photoconversion layer can further contain a material selected from the group consisting of fullerenes, carbon nanotubes, conjugated polymers, one or more types of interconnected metal oxide nanoparticles and combinations thereof. Other types of photoconversion materials known to those skilled in the art can be used with the Plasmon-enhanced photovoltaic device of the present invention.

To estimate the enhancement of the photoconversion efficiency with the Plasmon-enhanced photovoltaic device of the present invention employing near-percolation layer of plasmonic nanostructures, one can use the following calculations. To quantify the percolation behavior, lets introduce the parameter τ, which describes how close is the composite to the percolation condition: τ=(fₘ−p_{c})/p_{c}, where the fₘ is the volumetric filling fraction of plasmonic nanoparticles in the composite, p_{c} is the volumetric filling fraction of plasmonic nanoparticles corresponding to the percolation threshold. Scaling model (see [V. M. Shalaev, Physics Reports 272 (1996), 61-137]) provides the following estimation of the effective dielectric constant of the composite material was found to be reasonably accurate

$$\frac{{ɛ}^{( eff )}}{{ɛ}_{m}} = {\vert {f}_{m} - {p}_{c} \vert}^{t} S ( \frac{{ɛ}_{d} / {ɛ}_{m}}{{\vert {f}_{m} - {p}_{c} \vert}^{t + s}} ) ,$$

where ε^{(eff)} is the effective dielectric contact of the plasmonic nanostructure layer, εₘ is the dielectric constant of the plasmonic metal, e_{d} is the dielectric function of dielectric material where the plasmonic metal is embedded, and S(y) is a scaling function of complex variable y, which has the following asymptotic forms:

$$S ( y ) = \{ \begin{matrix}A + By + … & \vert y \vert << 1 & {f}_{m} > {p}_{c} \\ {B}^{′} y + … & \vert y \vert << 1 & {f}_{m} < {p}_{c} \\ {A}^{″} {y}^{t / ( t + s )} & \vert y \vert >> 1 & ∀ {f}_{m} .\end{matrix}$$

In this expression s and t are so-called percolation critical exponents which define the so-called fractal dimensionality and for three-dimensional composite t≈2.0 and s≈0.7 (see, e.g., [D. J. Bergman, D. Stroud, Solid State Phys. 46 (1992), p. 14] and [D. Stauffer, A. Aharony, An introduction to Percolation Theory, 2^{nd} Edition, Taylor and Francis, London, 1994]). From (4.40) under the assumption that W>>1 (near IR and longer wavelengths for gold) it follows:

$${ɛ}^{( eff )} \approx \{ \begin{matrix}{A}^{″} {ɛ}_{m}^{s / ( t + s )} {ɛ}_{d}^{t / ( t + s )} & \vert \frac{{ɛ}_{d}}{{ɛ}_{m}} \vert >> {\vert {f}_{m} - {p}_{c} \vert}^{t + s} & \\ {B}^{′} {ɛ}_{d} {\vert {f}_{m} - {p}_{c} \vert}^{- s} & \vert \frac{{ɛ}_{d}}{{ɛ}_{m}} \vert << {\vert {f}_{m} - {p}_{c} \vert}^{t + s} & {f}_{m} < {p}_{c} \\ B {ɛ}_{d} {\vert {f}_{m} - {p}_{c} \vert}^{- s} & \vert \frac{{ɛ}_{d}}{{ɛ}_{m}} \vert << {\vert {f}_{m} - {p}_{c} \vert}^{t + s} & {f}_{m} > {p}_{c} .\end{matrix}$$

The limit

$$\vert \frac{{ɛ}_{d}}{{ɛ}_{m}} \vert >> {\vert {f}_{m} - {p}_{c} \vert}^{t + s}$$

corresponds to the near IR spectral range and extremely close to percolation-threshold conditions. In this case the divergence of the dielectric function as metal concentration approaches percolation is not expected. if we will limit ourselves to the case of λ²/λₚ²>>1 (which is the case for Au and Ag in near IR), and will assume that

$$\sqrt{{A}^{″}} \frac{t}{t + s} \approx 1 ,$$

the electromagnetic field enhancement

$$\overline{G} = 〈 {\vert \overline{E} / {\overline{E}}_{0} \vert}^{2} 〉$$

can be estimated as (see [M. Gadenne et al., Europhys. Lett. 53 (3), pp. 364-370 (2001)]):

$${\overline{G}}^{3 D} ∼ C \frac{\vert {ɛ}_{m} \vert}{Im ( \vert {ɛ}_{m} \vert )} \cdot {( \frac{\vert {ɛ}_{m} \vert}{{ɛ}_{d}} )}^{\frac{v}{t + s}} ,$$

Where C can be approximated as a constant and ν is another critical exponent, approximately equal for 3D composites to 0.89. At λ²/λₚ²>>1 It is predicted that G̅^{3D} is independent on wavelength. For two-dimensional composites near the percolation threshold it is predicted (see, e.g., [V. A. Podolskiy et al., in Photonic Crystals and Light Localization in the 21st Century, pp. 567-575, Edited by C. M. Soukulis, Kluwer Academic Publishers, Netherlands]) that the field enhancement factor G̅^{2D} is wavelength dependent and can be estimated as

$${\overline{G}}^{2 D} ∼ {C}^{′} \frac{{\vert {ɛ}_{m} \vert}^{3 / 2}}{{ɛ}_{d} Im ( \vert {ɛ}_{m} \vert )} ∼ {λ}^{0.5} .$$

In order to further estimate the enhancement of the electromagnetic field in the near percolation plasmonic nanolayer, we can also follow [Genov D. A., et al., Nano Lett., Vol. 4 (1), pp. 153-158, (2004)] for analytical derivation of the field enhancement in two-dimensionally ordered array of plasmonic nanodiscs:

$$\overline{G} = 〈 {\vert \overline{E} / {\overline{E}}_{0} \vert}^{2} 〉 \approx \sqrt{\frac{{π ( W + 1 )}^{7 / 2}}{( ( 4 - π ) W + 4 ) {κ}^{7 / 2}} \sqrt{\begin{matrix}\frac{4 {Δ}^{2} + 9}{{( {Δ}^{2} + 1 )}^{3 / 2}} - \\ \frac{Δ ( 4 {Δ}^{4} + 15 {Δ}^{2} + 15 )}{{( {Δ}^{2} + 1 )}^{3}}\end{matrix}}}$$

Where W=|Re(εₘ)|/ε_{d}, Δ=(W/γ⁻¹)/κ, κ=−IM(εₘ)/Re(εₘ), γ=2d/(D−d), D is the period of the array, d is the diameter of the nanodisc. It should be noted that this equation was derived under the assumption of κ<<1 and γ>>1. This corresponds to close to percolation conditions and wavelengths in excess of 600 nm for gold, wavelength in excess of ˜500 nm for silver and ˜400 nm for aluminum (although for the case of aluminum this estimation is less accurate). Simulations are provided in FIG. 2 for gold as the plasmonic metal. One can see dramatic enhancement of the average intensity in the plasmonic near-percolation nanolayer (τ=0.1) compared to the prior art cases of far from percolation plasmonic nanostructures (τ=0.9).

Let's consider, for a nonlimiting example, the case of realization of the Plasmon enhanced photovoltaic device with organic photoconversion layer. Light absorption in this case, organic photovoltaic device usually leads to creation of excitons, which have high bounding energy and don't recombine into electron-hole pairs immediately, but rather remain bound and diffuse randomly until recombination occurs or until they reach an interface. The semiconductor-electrode interfaces can serve as a site for charge separation, but since the exciton diffusion length in polymers is typically only about 5-10 nm, very few of the excitons created are within reach of these interfaces in a conventional (prior art) organic PV device (to absorb more than 90% of sunlight at the organic PV layer absorption peak, the active layer should be ˜200 nm thick). The solution offered by the PV device of the present invention is envisioned to allow reducing the thickness of the active layer down to below 10 nm while not only maintaining enhanced absorption compared to 200 nm device at the absorption peak, but also drastically increase light harvesting at longer wavelengths as well.

An increased absorption originating from surface plasmon resonances, as well as increased extracted photocurrent from device confirmed experimentally using dilute plasmonic nanoparticles (see, e.g., [K. Tvingstedt et al., Surface plasmon increase absorption in polymer photovoltaic cells, APL 91, 113514, 2007]). However, in all prior art realizations of plasmonic-enhanced photovoltaic devices the majority of photocurrent was generated at the wavelength position of the plasmon resonance peak corresponding to the individual resonances of the nanoparticles or surface plasmon polaritons. The present invention teaches the use of nanocomposite based on metal nanostructures close to percolation threshold. In this case plasmon resonance-enhanced absorption can encompass much wider spectral range, extending well into the infrared range. The fields in the metal near percolation nanocomposites can be significantly enhanced leading toward much higher probability of electron-hole pare generation. This happens due to transition from localized plasmon modes on individual nanoparticles to delocalized (approaching continuum generation) plasmon modes on nanoparticle aggregates.

According to one aspect of the present embodiment said plasmonic nanostructure layer is composed of metal nanoparticles disposed near the active layer with the concentration of the nanoparticles being near the metal percolation threshold with τ parameter introduced previously in the range of 0.001 and 0.5 and said metal made of material selected from the group consisted of Au, Ag, Cu and Al.

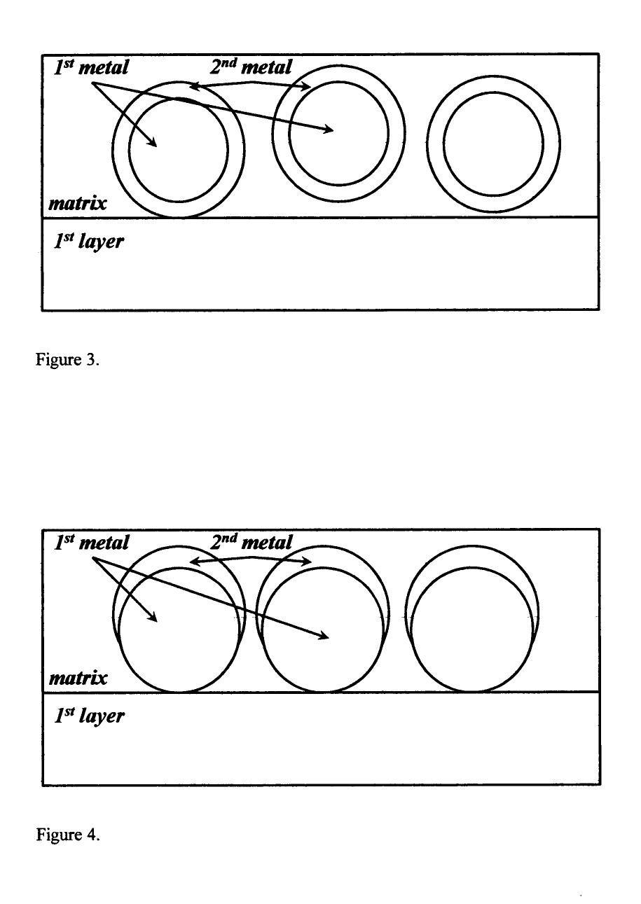

According to another aspect of the present embodiment said plasmonic nanostructure layer is composite of metal nanoparticles disposed near the active layer with the concentration of the nanoparticles being near the metal percolation threshold with τ parameter in the range of 0.001 and 0.75 and said metal nanoparticles comprise the nanolayered nanospheres with individual layers made of materials consisted of Au, Ag, Cu, Al and optionally metal and/or semiconductor oxides as shown in illustrative exemplary drawing in FIG. 3. Such a realization would provide wider spectral band of plasmon enhancement of PV conversion efficiency and will effectively solve the otherwise possible problem of reduction of the plasmonic absorption in the blue segment of the spectrum with approaching the percolation conditions.

According to still another aspect of the present embodiment said plasmonic nanostructure layer is composite of metal nanoparticles disposed near the active layer with the concentration of the nanoparticles being near the metal percolation threshold with τ parameter in the range of 0.001 and 0.75 and said metal nanoparticles comprise the nanolayered nanoellipsoids with individual layers made of materials consisted of Au, Ag, Cu, Al and optionally metal and/or semiconductor oxides as shown in illustrative exemplary drawing in FIG. 4. Such a realization would provide wider spectral band of plasmon enhancement of PV conversion efficiency and will effectively solve the otherwise possible problem of reduction of the plasmonic absorption in the blue segment of the spectrum with approaching the percolation conditions.

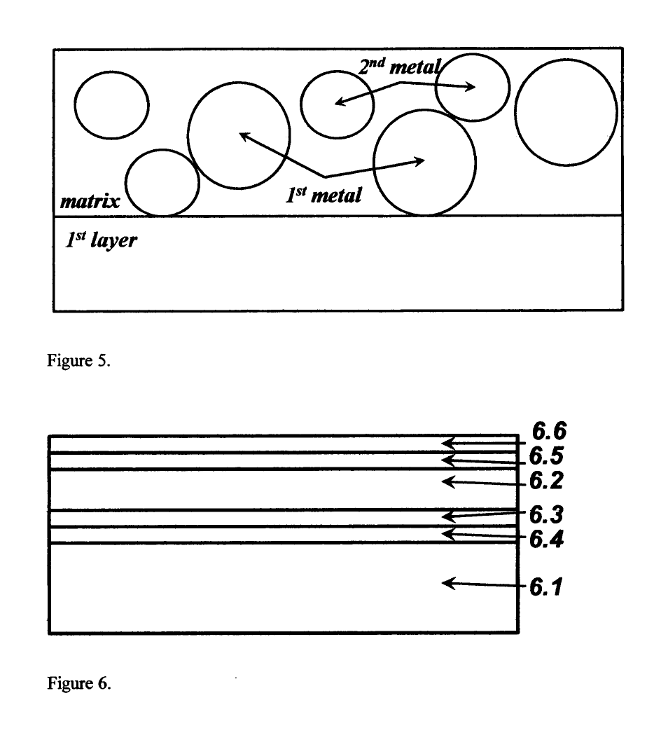

According to still another aspect of the present embodiment the plasmonic nanostructure layer is composed from nanoparticles of at least two different materials selected from the group consisted of Au, Ag, Cu and Al (as illustrated in FIG. 5), with total metal concentration in the range of 0.001 and 0.75 in terms of τ parameter. Such a realization would provide the wider band of plasmon enhancement of PV conversion efficiency.

According to still another aspect of the present embodiment the nanocomposite plasmonic layer is composed from nanoparticles of at least two different structures in a form of multilayer spheres or ellipsoids selected from the group consisted of Au, Ag, Cu and Al, and possibly metal oxides with total nanoparticle concentration in the range of 0.001 and 0.75 in terms of τ parameter. Such a realization would provide the wider band of plasmon enhancement of PV conversion efficiency.

According to still another aspect of the present embodiment said nanocomposite plasmonic layer is composed of metal nanoparticles disposed near the active layer with the concentration of the nanoparticles being near the metal percolation threshold with τ parameter in the range of 0.001 and 0.5 and said metal being an alloy, comprising two or more materials of material selected from the group consisted of Au, Ag, Cu, Al, Si, Ni, Mo, Ta, Ti, Co, Fe.

According to the second embodiment of the present invention the Plasmon-enhanced photovoltaic device shown in FIG. 6 is comprising a substrate 6.1, a plasmonic nanostructure layer 6.3 disposed on said substrate, said plasmonic nanostructure layer having concentration of metal close to percolation threshold, at least one photoconversion layer 6.2 disposed on said plasmonic nanostructure layer, and at least two electrodes 6.4 and 6.5, a first of which electrodes is in electrical contact with a first charge collection region of photoconversion layer in which electrical charges of a first polarity are concentrated, and a second of which electrodes is in electrical contact with a second charge collection region of said photoconversion layer in which electrical charges of a second polarity are concentrated. Additional protection and/or antireflection layer 6.6 can be employed in photovoltaic device as well to further improve the performance.

All aspects disclosed in relation to the first embodiment are equally applicable in relation to this embodiment as well.

According to still another embodiment of the present invention two or more layers of plasmonic nanostructures are used in a photovoltaic device with each of said layers having the structure described in previous embodiments of the present invention.

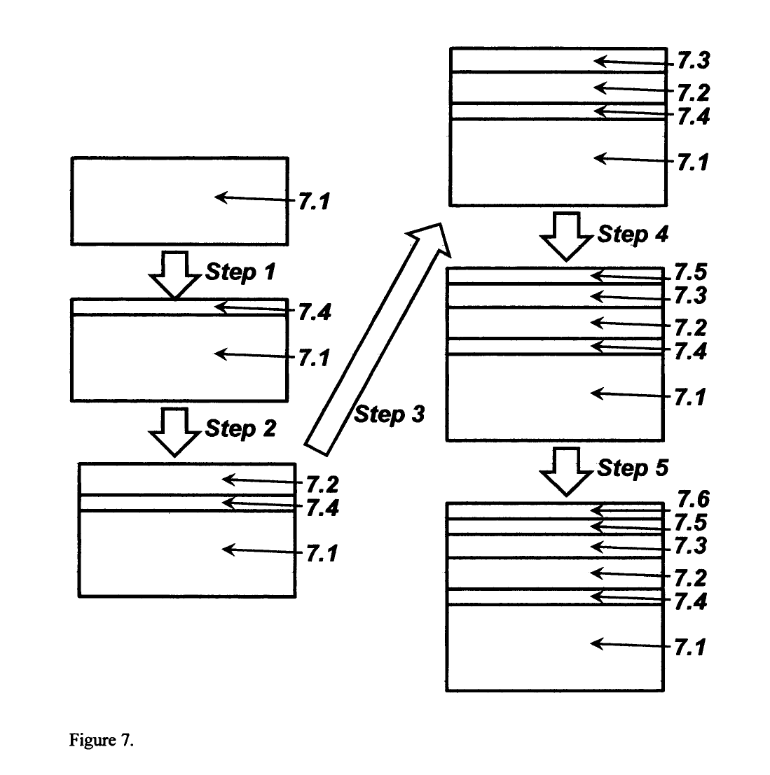

According to the third embodiment of the present invention the method of manufacturing of a Plasmon-enhanced photovoltaic device comprises, as illustrated in FIG. 7: providing a substrate 7.1, applying, onto said substrate, first electrode 7.4, applying, onto said first electrode, a plasmonic nanostructure layer made of metal 7.2, said plasmonic nanostructure layer having concentration of metal close to percolation threshold, applying a photoconversion layer onto said plasmonic nanostructure layer, 7.3 and applying, onto said photoconversion layer a second electrode 7.5. Optionally, the second electrode can be coated with antireflection and/or protection layer 7.6.

Deposition of the first electrode (Step 1 in FIG. 7) and second electrode (Step 4 in FIG. 7) can be performed by physical vapor deposition (magnetron sputtering, Ion Assisted Ion Beam Deposition, Thermal Evaporation), chemical vapor deposition (including but not limited to metal-organic chemical vapor deposition, low pressure chemical vapor deposition and atomic layer deposition), electro deposition or by any other suitable deposition technique known to those skilled in the art.

Deposition of the plasmonic nanostructured layer (Step 2 in FIG. 7) can be performed by using the process of chemical synthesis, deposition, sputtering, coating, electrodeposition, electroless deposition, self assembly or any other method know by those skilled in the art. Alternatively, the deposition of plasmonic nanostructured layer can comprise deposition of one or more metal film with consequent patterning by photolithography and follow on etching, which can be chemical etching or ion milling.

Deposition of photoconversion layer (Step 3 in FIG. 7) can be performed by physical vapor deposition (magnetron sputtering, Ion Assisted Ion Beam Deposition, Thermal Evaporation), chemical vapor deposition (including but not limited to metal-organic chemical vapor deposition, low pressure chemical vapor deposition and atomic layer deposition), electro deposition or by any other suitable deposition technique known to those skilled in the art.

Deposition of antireflective and/or protecting layer (Step 5 in FIG. 7) can be performed by physical vapor deposition (magnetron sputtering, Ion Assisted Ion Beam Deposition, Thermal Evaporation), chemical vapor deposition (including but not limited to metal-organic chemical vapor deposition, low pressure chemical vapor deposition and atomic layer deposition), electro deposition or by any other suitable deposition technique known to those skilled in the art.

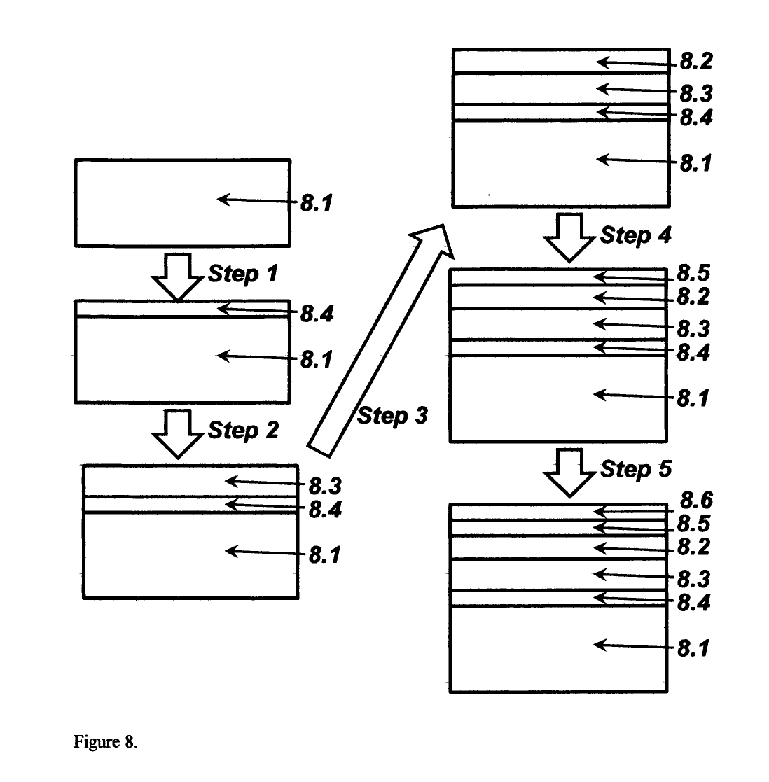

A method of manufacturing a Plasmon-enhanced photovoltaic device according to the forth embodiment of the present invention comprises, as illustrated in FIG. 8: providing a substrate 8.1, applying, onto said substrate, first electrode 8.4, applying, onto said first electrode, a photoconversion layer 8.3, applying, onto said photoconversion layer, a plasmonic nanostructure layer 8.2 made of metal, said plasmonic nanostructure layer having concentration of metal close to percolation threshold, applying and applying, onto said photoconversion layer a second electrode. Optionally, the second electrode can be coated with antireflection and/or protection layer 8.6. Manufacturing steps in this embodiment are similar to those previously disclosed in relation to the third embodiment of the present invention.

The photovoltaic structure of the present invention can be used in solar energy generation, photovoltaic conversion, photon detection and in other applications of photovoltaic structure presently known to those skilled in the art.

While the invention has been particularly shown and described with reference to specific illustrative embodiments, it should be understood that various changes in the form and detail may be made without departing from the spirit and scope of the invention as defined by appended claims.

What is claimed is:

1. A Plasmon-enhanced photovoltaic device comprising:
a substrate;
at least one photoconversion layer disposed on said substrate, said photoconversion layer having a surface, and two charge collection regions;
a plasmonic nanostructure layer made of metal and disposed on said surface of said at least one photoconversion layer, said plasmonic nanostructure layer having plasmonic modes of electromagnetic field, such as electromagnetic field of said plasmonic modes is at least partially localized in said photoconversion layer; said plasmonic nanostructure layer having concentration of metal close to percolation threshold.
and at least two electrodes, a first of which electrodes is in electrical contact with a first charge collection region of said photoconversion layer in which electrical charges of a first polarity are concentrated, and a second of which electrodes is in electrical contact with a second charge collection region of said photoconversion layer in which electrical charges of a second polarity are concentrated; said Plasmon-enhanced photovoltaic device configured to generate an electrical potential between said first and said second electrodes when said Plasmon-enhanced photovoltaic device is illuminated with electromagnetic radiation.

2. The device of claim 1, wherein said at least one photoconversion layer is a polycrystalline semiconductor thin film, said semiconductor material is selected from the group consisting of silicon, GaAs, CdTe, CuInGaSe (CIGS), CdSe, PbS, and PbSe.

3. The device of claim 1 wherein said at least one photoconversion layer is an epitaxial semiconductor thin film, said semiconductor material is selected from the group consisting of silicon, GaAs, CdTe, CuInGaSe (CIGS), CdSe, PbS, and PbSe.

4. The device of claim 1 wherein said at least one photoconversion layer comprises a photosensitized nanomatrix material.

5. The device of claim 4 wherein said photosensitized nanomatrix material comprises nanoparticles.

6. The device of claim 4 wherein said photosensitized nanomatrix material comprises one or more types of interconnected metal oxide nanoparticles, said metal oxide has the formula MA wherein M is selected from the group consisting of Ti, Zr, W, Nb, La, Ta, Tb, Sn, and Zn; and x and y are integers greater than 0.

7. The device of claim 6, wherein the metal oxide nanoparticles are interconnected by a polymeric linking agent.

8. The device of claim 4, wherein said photosensitized nanomatrix material comprises a photosensitizing agent selected from the group consisting of dyes, xanthenes, cyanines, merocyanines, phthalocyanines, and pyrroles.

9. The device of claim 1, wherein said photoconversion layer is made of heterojunction composite material.

10. The device of claim 1, wherein the photoconversion layer is made of a material selected from the group consisting of fullerenes, carbon nanotubes, conjugated polymers, one or more types of interconnected metal oxide nanoparticles and combinations thereof.

11. The device of claim 1, wherein said plasmonic nanostructure layer comprises a layer of plasmonic nanoparticles that are made of metal selected from the group consisting of silver, gold, copper and aluminum.

12. The device of claim 11, wherein said layer of plasmonic nanoparticles is composed from plasmonic nanoparticles of at least two different materials selected from the group consisted of silver, gold, copper and aluminum.

13. The device of claim 11, wherein said layer of plasmonic nanoparticles is composed from nanoparticles which comprise the nanolayered nanospheres with at least two individual layers made of materials selected from the group consisted of silver, gold, copper, aluminum metal oxides and semiconductor oxides.

14. The device of claim 11, wherein said layer of plasmonic nanoparticles is composed from nanoparticles which comprise the nanolayered nanoellipsoids with at least two individual layers made of materials selected from the group consisted of silver, gold, copper aluminum, metal oxides and semiconductor oxides.

15. The device of claim 1, wherein said plasmonic nanostructure layer comprises a layer of plasmonic nanoislands that are made of metal selected from the group consisting of silver, gold, copper and aluminum.

16. The device of claim 1, wherein said plasmonic nanostructure layer comprises a regular array of plasmonic nanoinclusions.

17. The device of claim 1, wherein said Plasmon-enhanced photovoltaic device further comprising protecting layer.

18. A Plasmon-enhanced photovoltaic device comprising:
a substrate;
at least one photoconversion layer, said photoconversion layer two charge collection regions;
a plasmonic nanostructure layer made of metal and disposed on said substrate, said plasmonic nanostructure layer having plasmonic modes of electromagnetic field, such as electromagnetic field of said plasmonic modes is at least partially localized in said photoconversion layer; said plasmonic nanostructure layer having concentration of metal close to percolation threshold.
and at least two electrodes, a first of which electrodes is in electrical contact with a first charge collection region of said photoconversion layer in which electrical charges of a first polarity are concentrated, and a second of which electrodes is in electrical contact with a second charge collection region of said photoconversion layer in which electrical charges of a second polarity are concentrated; said Plasmon-enhanced photovoltaic device configured to generate an electrical potential between said first and said second electrodes when said Plasmon-enhanced photovoltaic device is illuminated with electromagnetic radiation.

19. The device of claim 18, wherein said at least one photoconversion layer is a polycrystalline semiconductor thin film, said semiconductor material is selected from the group consisting of silicon, GaAs, CdTe, CuInGaSe (CIGS), CdSe, PbS, and PbSe.

20. The device of claim 18 wherein said at least one photoconversion layer is an epitaxial semiconductor thin film, said semiconductor material is selected from the group consisting of silicon, GaAs, CdTe, CuInGaSe (CIGS), CdSe, PbS, and PbSe.

21. The device of claim 18 wherein said at least one photoconversion layer comprises a photosensitized nanomatrix material.

22. The device of claim 21 wherein said photosensitized nanomatrix material comprises nanoparticles.

23. The device of claim 21 wherein said photosensitized nanomatrix material comprises one or more types of interconnected metal oxide nanoparticles, said metal oxide has the formula MₓP_{y} wherein M is selected from the group consisting of Ti, Zr, W, Nb, La, Ta, Tb, Sn, and Zn; and x and y are integers greater than 0.

24. The device of claim 23, wherein the metal oxide nanoparticles are interconnected by a polymeric linking agent.

25. The device of claim 21, wherein said photosensitized nanomatrix material comprises a photosensitizing agent selected from the group consisting of dyes, xanthenes, cyanines, merocyanines, phthalocyanines, and pyrroles.

26. The device of claim 18, wherein said photoconversion layer is made of heterojunction composite material.

27. The device of claim 18, wherein the photoconversion layer is made of a material selected from the group consisting of fullerenes, carbon nanotubes, conjugated polymers, one or more types of interconnected metal oxide nanoparticles and combinations thereof.

28. The device of claim 18, wherein said plasmonic nanostructure layer comprises a layer of plasmonic nanoparticles that are made of metal selected from the group consisting of silver, gold, copper and aluminum.

29. The device of claim 28, wherein said layer of plasmonic nanoparticles is composed from plasmonic nanoparticles of at least two different materials selected from the group consisted of silver, gold, copper and aluminum.

30. The device of claim 28, wherein said layer of plasmonic nanoparticles is composed from nanoparticles which comprise the nanolayered nanospheres with at least two individual layers made of materials selected from the group consisted of silver, gold, copper, aluminum metal oxides and semiconductor oxides.

31. The device of claim 28, wherein said layer of plasmonic nanoparticles is composed from nanoparticles which comprise the nanolayered nanoellipsoids with at least two individual layers made of materials selected from the group consisted of silver, gold, copper aluminum, metal oxides and semiconductor oxides.

32. The device of claim 18, wherein said plasmonic nanostructure layer comprises a layer of plasmonic nanoislands that are made of metal selected from the group consisting of silver, gold, copper and aluminum.

33. The device of claim 18, wherein said plasmonic nanostructure layer comprises a regular array of plasmonic nanoinclusions.

34. The device of claim 1, wherein said Plasmon-enhanced photovoltaic device further comprising protecting layer.

35. A method of manufacturing a Plasmon-enhanced photovoltaic device: providing a substrate, applying, onto said substrate, first electrode, applying, onto said first electrode, a plasmonic nanostructure layer made of metal, said plasmonic nanostructure layer having concentration of metal close to percolation threshold, applying, onto said plasmonic nanostructure layer, a photoconversion layer, and applying, onto said photoconversion layer a second electrode.

36. A method of manufacturing a Plasmon-enhanced photovoltaic device: providing a substrate, applying, onto said substrate, first electrode, applying, onto said first electrode, a photoconversion layer, applying, onto said photoconversion layer, a plasmonic nanostructure layer made of metal, said plasmonic nanostructure layer having concentration of metal close to percolation threshold, applying and applying, onto said photoconversion layer a second electrode.
